(19) United States
(12) Patent Application Publication
(10) Pub. No.: US 2026/0050218 A1
(43) Pub. Date: Feb. 19, 2026

(54) PHENOLIC HYDROXYL GROUP-CONTAINING BRANCHED ORGANOPOLYSILOXANE, HIGH ENERGY RAY-CURABLE COMPOSITION CONTAINING SAME, AND USE THEREOF

(71) Applicant: DOW TORAY CO., LTD., Shinagawa-Ku, Tokyo (JP)

(72) Inventors: Liang WENBIN, Ichihara-Shi, Chiba (JP); Takuya OGAWA, Ichihara-shi, Chiba (JP)

(21) Appl. No.: 19/102,279

(22) PCT Filed: Jul. 25, 2023
(86) PCT No.: PCT/JP2023/027139

§ 371 Date: Feb. 7, 2025

(30) Foreign Application Priority Data
Aug. 8, 2022 (JP) 2022-126480

(51) Int. Cl. G03F 7/075; C08G 77/00; C08G 77/04

(52) U.S. Cl. CPC G03F 7/0757; C08G 77/045; C08G 77/80

(57) ABSTRACT

Provided is a curable reactive organopolysiloxane having favorable alkali solubility and a high energy beam-curable composition containing the same. Specifically, provided is a phenolic hydroxyl group-containing branched organopolysiloxane expressed by the following average unit formula (1): (A₃SiO_{1/2})ₐ(A₂SiO_{2/2})_{b}(RSiO_{3/2})_{c}(SiO_{4/2})_{d}. In formula (1), R is a monovalent hydrocarbon group or the like; A is group selected from the same groups as R and group M¹ is expressed by formula (21) described herein, where in formula (21), R¹ is a divalent hydrocarbon group having 2 to 6 carbon atoms, X is a hydroxyl group, Z is a monovalent group expressed by —OR³ (where R³ is an acid-dissociable group), m1 is 1 to 3, and k is 0 to 3. At least one of all A is M¹, and a, b, c, and d satisfy the following conditions: 0≤a, 0≤b, 0<(a+b), and 0<(c+d).

### TECHNICAL FIELD

The present invention relates to an alkali soluble phenolic hydroxyl group-containing branched organopolysiloxane which can be cured by actinic rays, for example high energy beams or electron beams, and to a high energy beam-curable composition containing the same. The phenolic hydroxyl group-containing branched organopolysiloxane of the present invention has high solubility in alkaline aqueous solutions and favorable high energy beam curability, and therefore exhibits excellent lithography performance and is suitable as a resist material or insulating material for electronic and electric devices that require patterning, and in particular as a material for use as a coating agent.

### BACKGROUND ART

Due to high heat resistance and excellent chemical stability, silicone resins have been used as coating agents, potting agents, insulating materials, and the like for electronic and electrical devices. Among silicone resins, high energy beam-curable silicone compositions have also been reported.

Touch panels are used in various display devices such as mobile devices, industrial equipment, car navigation systems, and the like. In order to improve detection sensitivity, electrical influence from light emitting sites such as light-emitting diodes (LED), organic EL devices (OLED), and the like must be suppressed, and an insulating layer is usually placed between the light-emitting part and the touchscreen. On the other hand, thin display devices such as OLEDs and the like have a structure in which a plurality of functional thin layers are stacked. In recent years, studies have been conducted to improve the visibility of display devices by laminating insulating layers formed from acrylate polymer with a high refractive index and multifunctional polymerizable monomers, above and below the touchscreen layer. (For example, see Patent Documents 1 and 2)

Advances in photolithography technology have enabled achieving finer patterns in the manufacture of semiconductor devices, and the progress has been remarkable in recent years. The technique for achieving this miniaturization generally involves using light sources with shorter wavelengths, and resist materials using electron beams and extreme ultraviolet (EUV) rays are being investigated for use in regions with a resolution of 20 nm or less. With technology using EUV, excitation of the resist material itself by irradiation is important, and polymers having phenol groups are being actively studied as EUV resist materials. Patent Document 3 discloses a resist composition that contains an acrylic polymer having a phenol group and a specific acid generating agent and has favorable stability over time.

Similarly, silicone-based resist materials are also being considered, taking advantage of their excellent etching resistance. Patent Document 4 discloses a resist composition containing a phenol-functional polysiloxane which is a reaction product of a hydrogen-functional polysiloxane, an alkenyl-functional polysiloxane, and a specific diallyl compound. However, since linear polysiloxane components are abundant, the product does not exhibit alkali solubility. Furthermore, Patent Documents 5 and 6 disclose phenol-functional polysilsesquioxanes having a specific structure and resist compositions. These are alkali soluble, but there are problems with solubility. Furthermore, Patent Document 7 discloses a photosensitive resin composition containing a mixture of a polysiloxane having an acetal-protected phenolic hydroxyl group and a polysiloxane having a cationically curable group and a phenolic hydroxyl group. The composition described therein is also alkali soluble, but no consideration has been given to polysiloxanes that do not contain cationic curable groups and contain only phenolic hydroxyl groups.

In other words, although phenol-functional polysiloxanes and high energy beam-curable compositions containing these have been disclosed, it is difficult to say that a curable organopolysiloxane in which the polysiloxane itself has high solubility in an aqueous alkaline solution and exhibits excellent high energy beam curability, and a high energy beam-curable composition containing the same have been sufficiently disclosed.

### RELATED ART DOCUMENTS

### Patent Documents

[Patent Document 1] Japanese Unexamined Patent Application 2013-140229

[Patent Document 2] Japanese Unexamined Patent Application 2021-61056

[Patent Document 3] Japanese Unexamined Patent Application 2017-227733

[Patent Document 4] Japanese Unexamined Patent Application 2004-262952

[Patent Document 5] Japanese Unexamined Patent Application 2016-212350

[Patent Document 6] Japanese Unexamined Patent Application 2005-283991

[Patent Document 7] WO2016-52391

### SUMMARY OF THE INVENTION

### Problem to be Solved by the Invention

As described above, there is still a need for curable reactive organopolysiloxanes that have favorable alkali solubility and high energy beam curability, and high energy beam-curable compositions containing the same.

### Means for Solving the Problem

In order to resolve the aforementioned problems, the present invention was achieved based on a discovery that an organopolysiloxane having a specific branched structure and having a phenolic hydroxyl group-containing organic group on a silicon atom has high solubility in an alkaline aqueous solution, and that a high energy beam-curable composition containing the same has excellent coatability to a base material and excellent alkali solubility, exhibits favorable curability, and a cured product (cured film) thereof has sufficient mechanical strength and favorable transparency.

In other words, an object of the present invention can be satisfactorily achieved by a phenolic hydroxyl group-containing branched organopolysiloxane having a specific structure, a curable composition containing the same, and use thereof. Herein, the curable composition is cured by forming a chemical bond due to the curing reactivity of the specific phenolic hydroxyl group-containing organic group of the present invention (particularly, curing reactivity with high energy beams or the like). The curing means, or the like is not particularly limited, but the curable composition is preferably in the form of a high energy beam-curable composition in which the curing reaction proceeds by irradiation with a high energy beam or electron beam.

The phenolic hydroxyl group-containing branched organopolysiloxane of the present invention is expressed by the following average unit formula (1).

### Average Unit Formula (1):

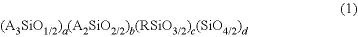

{In the formula, R represents a group selected from hydrogen atoms, unsubstituted or fluorine-substituted monovalent hydrocarbon groups, alkoxy groups, and hydroxyl groups;
each A independently represents one or more group selected from the same groups as R, groups M¹ expressed by the following formula (21):

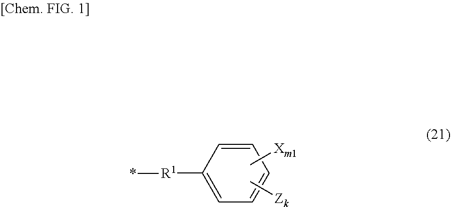

(where R¹ is a divalent hydrocarbon group having 2 to 6 carbon atoms, X is a hydroxyl group, Z is a monovalent group expressed by —OR³ (where R³ is an acid-dissociable group), m1 is a number in a range of 1 to 3, k is a number in a range of 0 to 3, and * is a silicon atom-bonding site on the organopolysiloxane),
groups M² is expressed by the following formula (22):

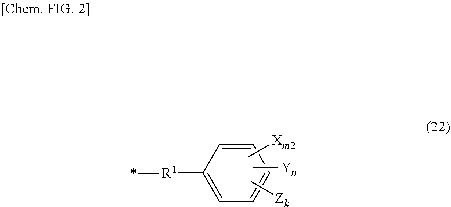

(In the formula, R¹, X, and Z are the same groups as described above,
Y is a monovalent hydrophilic group expressed by —Wₚ—R²_{q}—CO₂H (where W represents a divalent linking group selected from O(C═O), NR₅(C═O), and S(C═O) groups, p is 0 or 1,
q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group),
m2 is 0 or 1, n is a number in a range of 1 to 3, k is a number in a range of 0 to 3, and * is a silicon atom-bonding site on the organopolysiloxane),
groups J expressed by the following formula (3):

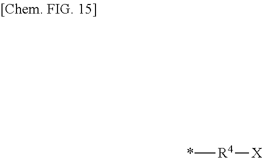

(in the formula, R⁴ represents a divalent hydrocarbon group with 2 to 6 carbon atoms, and X represents the aforementioned groups); and
groups L expressed by the following formula (4):

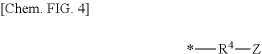

(in the formula, R⁴ and Z represents the same groups as described above); and
at least one of all A represents M¹, and a, b, c, and d are numbers satisfying the following conditions: 0≤a, 0≤b, 0<(a+b), and 0<(c+d)}.

The number of silicon atoms in the molecule of the phenolic hydroxyl group-containing branched organopolysiloxane may be 50 or less, or may be in a range of 5 to 20.

In the average unit formula (1) of the phenolic hydroxyl group-containing branched organopolysiloxane, “a” may be 1 or more, and similarly, “b” may be 0 in the average unit formula (1). Furthermore, in the above average unit formula (1) of the phenolic hydroxyl group-containing branched organopolysiloxane, a, b, c, and d may be numbers which further satisfy the following condition: 0.5≤a/(b+c+d)≤2.0.

The phenolic hydroxyl group-containing branched organopolysiloxane may be expressed by the following average unit formulas (1-1) or (1-2).

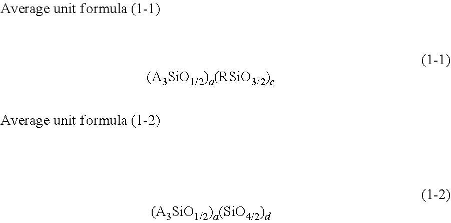

(In these formulas, R and A are the same groups as defined above, and a, c, and d are numbers satisfying the above conditions.)

The phenolic hydroxyl group-containing branched organopolysiloxane may have a weight average molecular weight, measured by gel permeation chromatography calculated based on a polystyrene standard, of 1,000 or more and 3,000 or less, and a polydispersity index (PDI) relating to the molecular weight distribution of 1.5 or less.

In the phenolic hydroxyl group-containing branched organopolysiloxane, m1 in the above formula (21) may be 1 or 2. Furthermore, in the phenolic hydroxyl group-containing branched organopolysiloxane, k in the above formula (21) and formula (22) may be 0, and a group L may not be included in the molecule.

The phenolic hydroxyl group-containing branched organopolysiloxane may be soluble in an aqueous alkaline solution so as to have a mass reduction rate of 90 mass % or more when the phenolic hydroxyl group-containing branched organopolysiloxane is applied to a glass plate so that the thickness after application is 0.5 μm, after which the coating film is immersed in a 2.38 mass % aqueous solution of tetramethylammonium hydroxide (TMAH) for 1 minute and then washed with water.

The present invention further provides a curable composition, particularly a high energy beam-curable composition, which contains the aforementioned phenolic hydroxyl group-containing branched organopolysiloxane. Specifically,
a high energy beam-curable composition is provided, containing at least the following components:
(A) the aforementioned curable branched organopolysiloxane;
(B) a photoacid generating agent in an amount of 0.1 to 20 parts by mass per 100 parts by mass of component (A);
(C) a crosslinking agent in an amount of 0 to 30 parts by mass per 100 parts by mass of component (A);
and
(D) an organic solvent.

The present invention further provides an insulating coating agent containing the high energy beam-curable composition described above. The present invention also provides a resist material containing the aforementioned high energy beam-curable composition.

The present invention further provides a cured product of the aforementioned high energy beam-curable composition. Furthermore, the present invention also provides a method of using the cured product as an insulative coating layer.

The present invention further provides a display device such as a liquid crystal display, organic EL display, or organic EL flexible display that includes a layer containing a cured product of the aforementioned high energy beam-curable composition.

### Effect of the Invention

The phenolic hydroxyl group-containing branched organopolysiloxane of the present invention has favorable coatability on a substrate and demonstrates high solubility in an aqueous alkaline solution normally used in the development process performed to form a pattern of a desired shape. Therefore, unreacted and uncured organopolysiloxane and curable compositions containing this organopolysiloxane can be easily removed by a washing operation using an alkaline aqueous solution during the development process that accompanies selective high energy beam irradiation, enabling high-precision patterning with a simple process. Furthermore, the curable composition containing the phenolic hydroxyl group-containing branched organopolysiloxane of the present invention, in particular, the cured product formed from the high energy beam-curable composition, has the advantage of being optically transparent, and the hardness or the like can be designed across a wide range. Therefore, the curable composition of the present invention is useful as a resist material that uses a short wavelength light source, particularly EUV. Furthermore, the compound is useful as a material for an insulating layer for electronic devices, particularly for thin display devices such as OLEDs, particularly as a patterning material and a coating material.

### DESCRIPTION OF THE PREFERRED EMBODIMENTS

A configuration of the present invention will be further described in detail below. The phenolic hydroxyl group-containing branched organopolysiloxane of the present invention with a specific structure has a phenolic hydroxyl group on at least one silicon atom, and is soluble in an aqueous alkaline solution (sometimes referred to as “alkali soluble” in the present invention). The high energy beam-curable composition of the present invention contains, as essential components, (A) the branched organopolysiloxane, (B) a photoacid generating agent, and (D) an organic solvent, and may also optionally contain (C) a crosslinking agent. However, if the branched organopolysiloxane (A) does not contain a carboxylic acid-containing organic compound, a crosslinking agent (C) is preferably included.

Alkaline solubility means that the formed coating film is soluble in the alkaline solution normally used in the development process to form a pattern of a desired shape. Well-known alkaline aqueous solutions include basic aqueous solutions of sodium hydroxide (NaOH), potassium hydroxide (KOH), quaternary ammonium salts, and the like, but aqueous solutions of KOH and tetramethylammonium hydroxide (TMAH) are typically used, and TMAH aqueous solutions are particularly widely used. In the present invention, this means that the material is soluble in an aqueous alkaline solution.

More specifically, “soluble in an aqueous alkaline solution” means that if the branched organopolysiloxane of the present invention is applied to a glass plate to a thickness of 0.5 μm, after which the coating film is immersed in a 2.38% aqueous solution of TMAH for 1 minute and then washed with water, the coating film made of the organopolysiloxane has a mass reduction rate of 90 mass % or more. In particular, if the coating film made of the organopolysiloxane has a mass reduction rate of 95 mass % or more, or 98 mass % or more when evaluated by the aforementioned method, the coating film can be considered to have particularly excellent solubility in an aqueous alkaline solution. Note that spin-coating or other methods are commonly used to apply the organopolysiloxane on a glass plate. If the coating is applied using an organic solvent, as described below, the organic solvent must be removed in advance by drying or other means. Furthermore, if the composition is mainly composed of organopolysiloxane, the solubility of the high energy beam-curable composition containing the organopolysiloxane of the present invention can be evaluated in an aqueous alkaline solution by the aforementioned method. Furthermore, the water washing process is generally performed by immersion in a water bath at about room temperature (25° C.) or by running water at about the speed of domestic tap water for 10 to 15 seconds, so as not to adversely affect the formed patterning or the substrate.

Note that the branched siloxane of the present invention includes one or more type selected from the aforementioned repeating units of (A₃SiO_{1/2}) and (A₂SiO_{2/2}) and thus tends to be more soluble in aqueous alkaline solutions compared to organopolysiloxanes containing only silsesquioxane units, so there is a tendency to produce organopolysiloxane with particularly excellent alkali solubility where the mass loss rate of the coating film is 90% or more, preferably 98% or more, when the solubility in an aqueous alkaline solution of a coating film containing branched organopolysiloxane including these siloxane units is evaluated by the method described above.

The phenolic hydroxyl group-containing branched organopolysiloxane of the present invention is expressed by the following average unit formula (1).

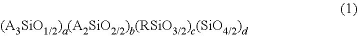

In the formula, R represents a group selected from hydrogen atoms, unsubstituted or fluorine-substituted monovalent hydrocarbon groups, alkoxy groups, and hydroxyl groups. The unsubstituted or fluorine-substituted monovalent hydrocarbon group is preferably a group selected from unsubstituted or fluorine substituted alkyl, cycloalkyl, arylalkyl, and aryl groups having 1 to 20 carbon atoms. Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups, but 3,3,3-trifluoropropyl groups are preferable. Examples of the alkoxy groups include methoxy groups, ethoxy groups, propoxy groups, and isopropoxy groups.

In the formula, each A independently represents one or more type selected from:
groups similar to R described above,
M¹ expressed by formula (21)

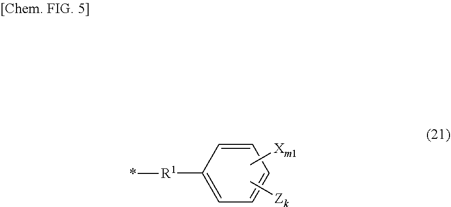

(wherein R¹ is a divalent hydrocarbon group having 2 to 6 carbon atoms, X is a hydroxyl group, Z is a monovalent group represented by —OR³ (wherein R³ is an acid-dissociable group), m1 is a number ranging from 1 to 3, k is a number ranging from 0 to 3, and * is a bonding site to a silicon atom on the organopolysiloxane);
M² expressed by the following formula (22)

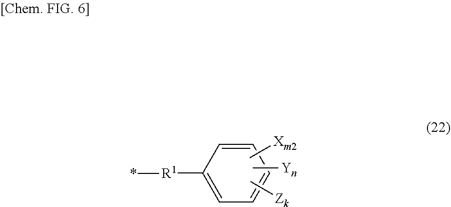

(In the formula, R¹, X, and Z are the same groups as described above,
Y is a monovalent hydrophilic group expressed by —Wₚ—R²_{q}—CO₂H (where W represents a divalent linking group selected from O(C═O), NR⁵(C═O), and S(C═O) groups, p is 0 or 1,
q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group),
m2 is 0 or 1, n is a number in a range of 1 to 3, k is a number in a range of 0 to 3, and * is a silicon atom-bonding site on the organopolysiloxane);
group J expressed by the following formula (3):

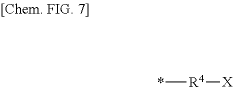

(in the formula, R⁴ represents a divalent hydrocarbon group with 2 to 6 carbon atoms, and X represents the aforementioned groups); and
group L expressed by the following formula (4):

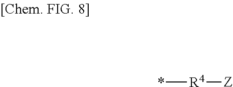

(in the formula, R⁴ and Z represent the same groups as described above); where
at least one of all A is M¹.

In other words, the phenolic hydroxyl group-containing branched organopolysiloxane of the present invention necessarily contains a phenolic hydroxyl group-containing organic group represented by M¹ in each molecule, and may optionally contain a carboxylic acid-containing organic group M², and may also contain a group selected from the alcoholic hydroxyl group-containing organic group J and the carboxylic acid-containing organic group L of formula (3) in the molecule. Note that the phenolic hydroxyl group-containing branched organopolysiloxane of the present invention may or may not contain group M² or group J in the molecule, but preferably does not contain group L.

There are no significant limitations on the ratio of each constituent unit in the phenolic hydroxyl group-containing branched organopolysiloxane expressed by the aforementioned average unit formula (1), but at least one of a and b is not zero. Similarly, at least one of c and d is not 0. Therefore, a, b, c, and d are numbers that satisfy the following conditions: 0≤a, 0≤b, 0<(a+b), and 0<(c+d).

Furthermore, the group M¹ may be present in either the (A₃SiO_{1/2}) unit or the (A₂SiO_{2/2}) unit, but one molecule has at least one group M¹. By setting the values of a, b, c, and d within appropriate ranges, the high energy beam curability, alkali solubility, and surface tackiness after application to a base material of the branched organopolysiloxane of the present invention can be appropriately controlled. However, in order to maintain a favorable balance between these characteristics, the values of a, b, c, and d are preferably set so as to satisfy the following formula:

$$0.5 \leq a / ( b + c + d ) \leq 2.0$$

Here, b is the number of (A₂SiO_{2/2}) units, but b=0 is also possible. In this case, at least one A in the (A₃SiO_{1/2}) unit in the molecule is a group M¹.

Furthermore, the preferable ranges of the ratios a/c and a/d of the siloxane units constituting the branched organopolysiloxane of the present invention can be expressed by the aforementioned relational expression 0.5≤a/(b+c+d)≤2.0. In other words, 0.5≤a/c≤2.0 and 0.5≤a/d≤2.0. Within these ranges, the aforementioned properties, namely, high energy beam curability, alkali solubility, and surface tackiness after application to a base material can be appropriately controlled.

A specific example of the phenolic hydroxyl group-containing branched organopolysiloxane that is preferably used in the present invention preferably contains monoorganosiloxy units (A₃SiO_{1/2}). In particular, the polymer may have one or more structures selected from the following average unit formulas (1-1) and (1-2). In other words, b in the aforementioned average unit formula (1) is preferably 0.

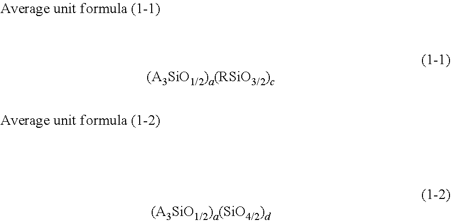

(In these formulas, R and A are the same groups as defined above, and a, c, and d are numbers satisfying the above conditions.)

The functional group M¹ is a group containing a phenolic hydroxyl group expressed by the aforementioned formula (21), and is a component that imparts curing reactivity in particular high energy beam curability, to the branched organopolysiloxane of the present invention by having a phenolic hydroxyl group (=substituent X). Herein, X is a hydroxyl group, and Z is a hydroxyl group protected by an acid-dissociable group R³ expressed by —OR³. X is a phenolic hydroxyl group, which exhibits hydrophilicity and contributes to improving the aforementioned alkali solubility in addition to the curing reactivity. On the other hand, Z does not exhibit hydrophilicity, but is a functional group that is useful for adjusting the hydrophilicity of the entire branched organopolysiloxane. Furthermore, in formula (21), the number m1 of substituents X on the aromatic ring is a number in a range of 1 to 3, and the number k of substituents Z is a number in a range of 0 to 3, and k may be 0. The positions of the substituents X and Z on the aromatic ring are not particularly limited.

R¹ is a linear or branched divalent hydrocarbon group having 2 to 6 carbon atoms, and is a linking group for the functional group M¹ expressed by formula (21) and the functional group M² expressed by formula (22). Specifically, examples of R¹ include methylene groups, ethylene groups, methylmethylene groups, propylene groups, methylethylene groups, butylene groups, and hexylene groups, but ethylene groups, methylmethylene groups, and propylene groups are preferable.

The substituent Z on the aromatic ring in the functional group M¹ expressed by formula (21) and the functional group M² expressed by formula (22), or the functional group Z in formula (4) is a monovalent group expressed by —OR³ (wherein R³ is an acid-dissociable group) and generates a hydroxyl group in the presence of a dilute acid. In other words, Z is a hydroxyl group protected by an acid-dissociable group R³.

Herein, R³ is an acid-dissociable group, which is easily decomposed in the presence of a dilute acid, such as acetic acid or formic acid, to generate a hydroxyl group from the functional group Z. Specifically, R³ is a linear or branched hydrocarbon group, a —(C═O)—R³¹ group (R³¹ is a linear monovalent hydrocarbon group, or a —R³²OR³³ group (R³² is a linear or branched divalent hydrocarbon group, and R³³ may be a linear monovalent hydrocarbon group), or a trialkylsilyl group. More specifically, examples include tert-butyl groups, acetyl groups, methoxymethyl groups, ethoxymethyl groups, ethoxyethyl groups, and trimethylsilyl groups. Of these, tert-butyl groups and trimethylsilyl groups are preferable.

m1 represents the number of hydroxyl groups (—X) on the aromatic ring in the functional group M¹ expressed by formula (21), and is a number ranging from 1 to 3, with 1 or 2 being preferable.

k represents the number of hydroxyl groups (—Z) protected by the acid-dissociable group R³ in the functional group M¹ expressed by formula (21) and the functional group M² expressed by formula (22), and is a number ranging from 0 to 3, preferably 0 or 1, and more preferably 0. In other words, the functional group Z is an optional functional group in the branched organopolysiloxane of the present invention, and is preferably not contained in the molecule.

The phenolic hydroxyl group-containing branched organopolysiloxane of the present invention may optionally contain a carboxylic acid-containing organic group, M². The alkali solubility of the branched organopolysiloxane of the present invention can be further improved by including functional group M² in addition to functional group M¹.

Substituent Y on the aromatic ring in the functional group M² expressed by formula (22) is a carboxylic acid-containing organic group expressed by —Wₚ—R²_{q}—CO₂H. In the formula, W on group Y is a divalent linking group containing a heteroatom, and is a group selected from ester groups O(C═O), amide groups NR⁵(C═O) (where R⁵ is a hydrogen atom or a methyl group), and thioester groups S(C═O). An ester group is preferably used in the phenolic hydroxyl group-containing branched organopolysiloxane of the present invention.

The linking group R² on group Y may be a linear, branched, or cyclic divalent hydrocarbon group with 2 to 12 carbon atoms containing an oxygen atom or a sulfur atom; a sulfur-containing linear, branched, or cyclic divalent hydrocarbon group; or an oxygen-containing linear, branched, or cyclic divalent hydrocarbon group. More specifically, the divalent group is exemplified by the following structural formula (7). Of these, the divalent linking groups represented by 6a, 6b, 6c, 6d, 6e, 6i, 6k, 6m, 6p, 6q, 6q, and 6s can be preferably used.

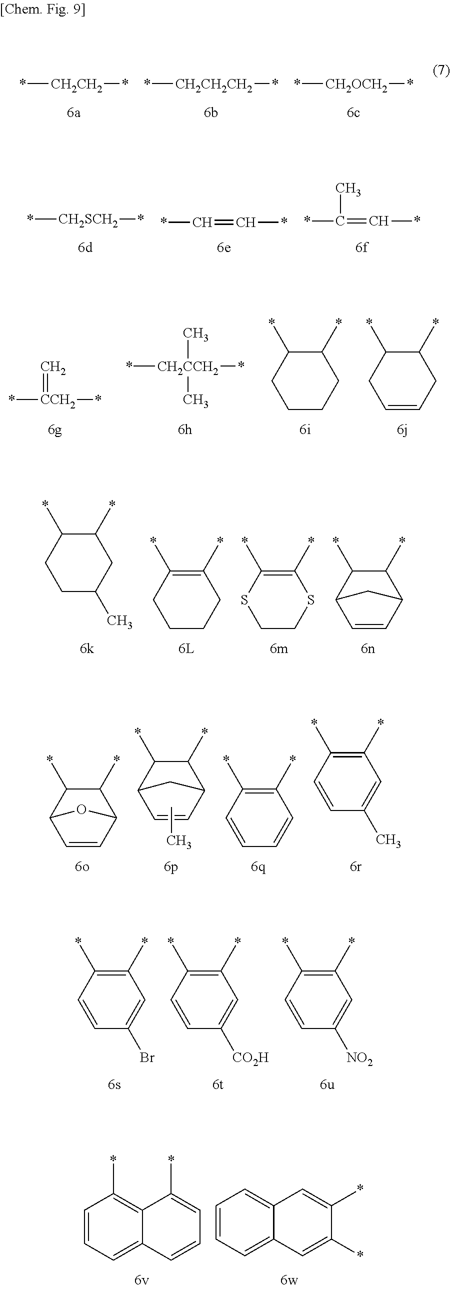

(In the formula, * indicates the binding site.)

In group Y, p is either 0 or 1, but is preferably 1. Furthermore, q is either 0 or 1, but is preferably 1.

m2 represents the number of hydroxyl groups (—X) on the aromatic ring in the functional group M² expressed by formula (22) and is either 0 or 1, but is preferably 0. Furthermore, n represents the number of the carboxylic acid-containing organic group, which is the substituent Y, on the aromatic ring in functional group M², and is a number in a range of 1 to 3, but is preferably 1. Incidentally, k is as described above.

From the perspective of achieving favorable curability using a high energy beam, if the phenolic hydroxyl group-containing branched organopolysiloxane of the present invention has a functional group M², the sum of the phenolic hydroxyl groups (X) in functional group M¹ and functional group M² in the entire molecule is greater than the sum of the carboxylic acid-containing organic groups (Y) in the functional group M². In other words, the value of [sum of the mass amount of hydroxyl groups (X) in groups M¹ and M² in the molecule]/[sum of mass amount of the carboxylic acid-containing hydrophilic groups (Y) in group M² in the molecule] is preferably 1 or more.

On the other hand, the co-modified branched organopolysiloxane of the present invention may optionally have a carboxylic acid-containing organic group expressed by M² in the molecule. The desired number of carboxylic acid groups in a molecule depends on the type and number of other substituents on the branched organopolysiloxane, but usually the introduction of one carboxylic acid group can further improve alkali solubility. If necessary, two or more carboxylic acid groups can be introduced into the molecule to impart even better alkali solubility.

Functional group J in the phenolic hydroxyl group-containing branched organopolysiloxane of the present invention is a group containing an alcoholic hydroxyl group and is expressed by the aforementioned formula (3). Group X in formula (3) is a hydroxyl group, as defined above. The linking group R⁴ is a linear or branched divalent hydrocarbon group having 2 to 6 carbon atoms. Specific examples include methylene groups, ethylene groups, methylmethylene groups, propylene groups, methylethylene groups, butylene groups, and hexylene groups. Of these, ethylene groups, methylmethylene groups, and propylene groups are preferable. Functional group J is an optional component of the phenolic hydroxyl group-containing branched organopolysiloxane according to the present invention, and is not required to be included in the molecule.

Functional group L in the phenolic hydroxyl group-containing branched organopolysiloxane of the present invention is a group containing a hydroxyl group (—Z) protected by an acid-dissociable group R³ via a linking group R⁴, as expressed by the aforementioned formula (4). Herein, R⁴ and Z in formula (4) are the same groups as defined above. Functional group L is an optional component of the phenolic hydroxyl group-containing branched organopolysiloxane of the present invention, is not required, and preferably is not included in the molecule.

From the perspective of controlling the molecular weight distribution of the polysiloxane to a small value in order to improve the coatability of the curable composition and lithography properties such as line width uniformity, the phenolic hydroxyl group-containing branched organopolysiloxane of the present invention preferably has 50 or fewer silicon atoms, more preferably 20 or fewer silicon atoms, and particularly preferably in a range of 3 to 50, and particularly preferably in a range of 5 to 20 silicon atoms.

Furthermore, there are no particular limitations on the molecular weight of the phenolic hydroxyl group-containing branched organopolysiloxane of the present invention, but when considering the coatability, high energy beam curability, alkali solubility, and mechanical strength properties of the coated film, the weight average molecular weight, calculated on the basis of a polystyrene standard, as measured by gel permeation chromatography is preferably 1000 to 3000, more preferably 1500 to 3000, and particularly preferably 1500 to 2500.

Similarly, from the perspective of improving the alkali solubility of the phenolic hydroxyl group-containing branched organopolysiloxane of the present invention, the polydispersity index (PDI), which relates to the molecular weight distribution as measured by gel permeation chromatography in the same manner as described above, is preferably 1.5 or less, and particularly preferably 1.4 or less.

The phenolic hydroxyl group-containing branched organopolysiloxane of the present invention contains at least one phenolic hydroxyl group-containing organic group represented by M¹ in the molecule. From the perspective of imparting favorable high energy beam curability and excellent alkali solubility, at least two hydroxyl groups (X) are preferably included in the molecule. Herein, at least one of the hydroxyl groups (X) in the molecule is a phenolic hydroxyl group derived from group M¹, but the other hydroxyl groups may be derived from a plurality of groups M¹, or selected from functional groups having a plurality of hydroxyl groups (X) on group M¹ or group M², or may be derived from group J. In other words, even if the number of phenolic hydroxyl groups (X) derived from group M¹ is small, the high energy beam curability and alkali solubility of the molecule as a whole can be further improved by implementing a molecular design in which the sum of the number of hydroxyl groups derived from group M¹, group M², and group J is large.

More specifically, the sum of the numbers of hydroxyl groups (X) derived from groups M¹, M², and J in the molecule of the phenolic hydroxyl group-containing branched organopolysiloxane of the present invention is preferably 2 or more on average, and more preferably 3 or more, 4 or more, or 5 or more. Note that in the organopolysiloxane expressed by the average unit formula (1), when a number of all As are group M¹ expressed by formula (21), number β of all As are group M² expressed by formula (22), and number Y of all As are group J expressed by formula (4), the sum of the numbers of hydroxyl groups (X) in the molecule is expressed by m1×α+m2×β+γ, and the sum of the numbers of X's is particularly preferably 2 or more, 3 or more, or 5 or more.

There are no particular limitations on the method for producing the phenolic hydroxyl group-containing branched organopolysiloxane of the present invention. Typical production methods include, but are not limited to, the following two methods: 1) producing a branched organopolysiloxane having a prescribed molecular weight and molecular weight distribution by a condensation reaction of a plurality of organosilicon compounds, and introducing a compound containing a phenolic hydroxyl group or a derivative thereof by a chemical reaction; and 2) producing an organosilicon compound containing a phenolic hydroxyl group or a derivative group thereof, and then producing a branched organopolysiloxane having a prescribed molecular weight and molecular weight distribution by a condensation reaction with another organosilicon compound. In the present invention, method 1) is preferably used. A specific example is a method in which a branched organopolysiloxane having silicon-bonded hydrogen atoms is produced, and then a phenolic hydroxyl group-containing group is introduced by a hydrosilylation reaction. In the latter reaction, a phenolic hydroxyl group-containing compound can be directly subjected to the reaction, or a method using a compound where the hydroxyl group is protected with an acid-dissociable group can be used, and then the protecting group is removed after introduction into the branched organopolysiloxane.

Particularly preferable is a method having at least a step of performing a hydrosilyl reaction of a silicon-bonded hydrogen atom-containing branched organopolysiloxane expressed by the following average unit formula (1′):

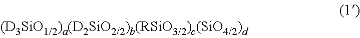

(In the formula, R is a group selected from hydrogen atoms, unsubstituted or fluorine-substituted monovalent hydrocarbon groups, alkoxy groups, and hydroxyl groups; each D is independently a group similar to R; at least one of all Ds is a hydrogen atom; and a, b, c, and d are numbers that satisfy the following conditions: 0≤a, 0≤b, 0<(a+b), and 0<(c+d));
particularly preferably a method that includes at least a step (I) of performing a hydrosilyl reaction between a silicon atom-bonded hydrogen atom-containing branched organopolysiloxane and a compound having an unsaturated hydrocarbon group expressed by formula (33):

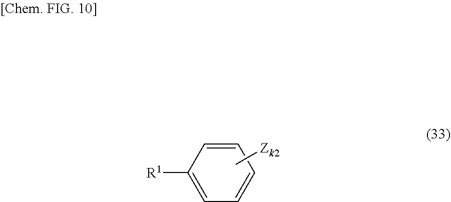

(In the formula, R⁶ is a monovalent unsaturated hydrocarbon group having 2 to 6 carbon atoms, Z is the same group as defined above, and k2 is a number ranging from 1 to 3); furthermore, particularly preferable is a method that, after the aforementioned step (I), further includes a step (II) of reacting one or more type of acidic substance with a branched organopolysiloxane having in a molecule a functional group expressed by the following formula (34):

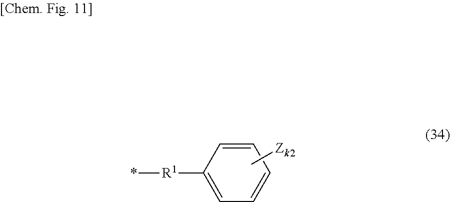

(In the formula, R¹ is a divalent hydrocarbon group having 2 to 6 carbon atoms, Z is the same group as defined above, k2 is the same number as defined above, and * is a bonding site to a silicon atom on the organopolysiloxane) to convert at least a portion of group Z to a hydroxyl group (X) in order to convert the functional group expressed by formula (34) to group M¹ expressed by formula (21).

Furthermore, a step (III) is possibly and preferably included after step (II), in which the branched organopolysiloxane having group M¹ expressed by formula (21) in the molecule obtained in step (II) is reacted with one or more types of acid anhydride to convert a portion of group M¹ to group M² expressed by formula (22), enabling introduction of a carboxylic acid-containing organic group into the molecule.

### [Curable Composition]

The phenolic hydroxyl group-containing branched organopolysiloxane of the present invention contains at least one phenolic hydroxyl group-containing organic group expressed by M¹ in the molecule, and has curing reactivity. The curing reaction mechanism is not particularly limited so long as the curing reaction involves the phenolic hydroxyl group, and examples include one or more reactions selected from condensation reactions, radical polymerization reactions, peroxide curing reactions, and high energy beam (for example, ultraviolet ray) curing reactions, and thus a curable composition containing the phenolic hydroxyl group-containing branched organopolysiloxane of the present invention can be designed.

### [High Energy Beam-Curable Composition]

The phenolic hydroxyl group-containing branched organopolysiloxane of the present invention has excellent alkali solubility and high energy beam curability, and is therefore particularly suitable for use in high energy beam-curable compositions. More specifically, the high energy beam-curable composition of the present invention contains at least the phenolic hydroxyl group-containing branched organopolysiloxane of the present invention and a photoacid generating agent necessary for curing, and may optionally contain other components.

More specifically, the high energy beam-curable composition of the present invention contains the following four components. Component (A) is the main component of the present invention as described. Note that, as described later, the crosslinking agent (C) is an optional component that may be added as necessary when component (A) does not have a carboxylic acid-containing organic group. Furthermore, the amount of the organic solvent used can be appropriately selected for the purpose of adjusting the coatability and other properties of the composition.
(A) the aforementioned phenolic hydroxyl group-containing branched organopolysiloxane;
(B) a photoacid generating agent in an amount of 0.1 to 20 parts by mass per 100 parts by mass of component (A);
(C) Crosslinking agent in an amount of 0 to 30 parts by mass per 100 parts by mass of component (A);
and
(D) an organic solvent.

### [Component (B): Photoacid Generating Agent]

Component (B) is a component that catalyzes the curing reaction of component (A) by a high energy beam, and a group of compounds known as photoacid generating agents for polymerization is usually applicable. Known photoacid generating agents are compounds capable of generating a Bronsted acid or a Lewis acid upon irradiation with a high energy beam or electron beam.

The photoacid generating agent used in the high energy beam-curable composition of the present invention can be arbitrarily selected from those known in the art and is not particularly limited to a specific type. Strong acid-generating compounds, such as diazonium salts, sulfonium salts, iodonium salts, phosphonium salts, and the like, are known photoacid generating agents, and these can be used. Examples of the photoacid generating agent include, but are not limited to; bis(4-tert-butylphenyl) iodonium hexafluorophosphate, cyclopropyldiphenylsulfonium tetrafluoroborate, dimethylphenacylsulfonium tetrafluoroborate, diphenyliodonium hexafluorophosphate, diphenyliodonium hexafluoroarsenate, diphenyliodonium tetrafluoromethanesulfonate, 2-(3,4-dimethoxystyryl)-4,6-bis(trichloromethyl)-1,3,5-triazine, 2-[2-(furan-2-yl)vinyl]-4,6-bis(trichloromethyl)-1,3,5-triazine, 4-isopropyl-4′-methyldiphenyliodonium tetrakis(pentafluorophenyl) borate, 2-[2-(5-methylfuran-2-yl) vinyl]-4,6-bis(trichloromethyl)-1,3,5-triazine, 2-(4-methoxyphenyl)-4,6-bis(trichloromethyl)-1,3,5-triazine, 2-(4-methoxystylyl)-4,6-bis(trichloromethyl)-1,3,5-triazine, 4-nitrobenzenediazonium tetrafluoroborate, triphenylsulfonium tetrafluoroborate, triphenylsulfonium bromide, tri-p-tolylsulfonium hexafluorophosphate, tri-p-tolylsulfonium trifluoromethanesulfonate, diphenyliodonium triflate, triphenylsulfonium triflate, diphenyliodonium nitrate, bis(4-tert-butylphenyl) iodonium perfluoro-1-butane sulfonate, bis(4-tert-butylphenyl) iodonium triflate, triphenylsulfonium perfluoro-1-butanesulfonate, N-hydroxynaphthalimide triflate, p-toluene sulfonate, diphenyliodonium p-toluenesulfonate, (4-tert-butylphenyl)diphenylsulfonium triflate, tris(4-tert-butylphenyl) sulfonium triflate, N-hydroxy-5-norbornene-2,3-dicarboxymide perfluoro-1-butanesulfonate, (4-phenylthiophenyl)diphenylsulfonium triflate, 4-(phenylthio) phenyldiphenylsulfonium triethyltrifluorophosphate, and the like. In addition to the aforementioned compounds, examples of the photocationic polymerization initiator include commercially available photoacid generating agents such as Omnicat 250, Omnicat 270 (both manufactured by IGM Resins BV), CPI-310B, IK-1 (both manufactured by San-Apro Co., Ltd.), DTS-200 (Midori Chemical Co., Ltd.), TS-01, TS-91 (both manufactured by Sanwa Chemical Co., Ltd.), and Irgacure 290 (BASF).

The amount of photoacid generating agent added to the high energy beam-curable composition of the present invention is not particularly limited, as long as the desired photocuring reaction occurs, but the photoacid generating agent is generally preferably used in an amount of 0.1 to 20 parts by mass, preferably 0.5 to 20 parts by mass, and particularly 1 to 10 parts by mass, per 100 parts by mass of the phenolic hydroxyl group-containing branched organopolysiloxane, which is component (A) of the present invention.

### [Component (C): Crosslinking Agent]

Component (C) is a component which reacts with a phenolic hydroxyl group by the action of an acid generated from component (B) due to irradiation with a high energy beam, and contributes to a crosslinking reaction. Component (C) can be a known crosslinking agent that is blended in a chemically amplified negative resist composition.

Examples of component (C) that are preferably used in the present invention include compounds having a plurality of alkoxymethyl groups on an amino group of an amino compound such as melamine, acetoguanamine, urea, ethyleneurea, glycoluril, and the like. Specific examples include hexamethoxymethylmelamine, tetramethoxymethylmonohydroxymethylmelamine, tetrakismethoxymethylglycoluril, tetrakisbutoxymethylglycoluril, dimethoxymethyldimethoxyethyleneurea, and the like. Of these, urea compounds, tetrakismethoxymethylglycoluril, tetrakisbutoxymethylglycoluril, and dimethoxymethyldimethoxyethyleneurea are preferably used. In addition to the aforementioned compounds, examples of component (C) include commercially available crosslinking agents such as Nikalac MW-390, MX-270, MX-279, MX-280 (all manufactured by Sanwa Chemical Co., Ltd.), and the like.

The amount of the crosslinking agent added to the high energy beam-curable composition of the present invention is not particularly limited so long as the desired photocuring reaction occurs. In other words, a crosslinking agent does not have to be added, but from the perspective of the photocuring reaction, 1 part by mass, and preferably 1 to 30 parts by mass, are preferably added to component (A), particularly when component (A) does not have a carboxylic acid-containing organic group. On the other hand, when component (A) is a co-modified branched organopolysiloxane having a carboxylic acid-containing organic group in the molecule, use of this component is optional, and the curing reaction will proceed even if a crosslinking agent is not added at all (see Example 4 described below). In the present invention, the crosslinking agent is preferably used in an amount of 0 to 30 parts by weight, preferably 5 to 30 parts by weight, and especially 10 to 30 parts by weight, per 100 parts by weight of the phenolic hydroxyl group-containing branched organopolysiloxane, which is component (A) of the present invention.

### [Component (D): Organic Solvent]

The high energy beam-curable composition of the present invention preferably contains (D) an organic solvent for the purposes of adjusting the coatability of the phenolic hydroxyl group-containing branched organopolysiloxane, coating conditions, the overall viscosity of the composition, and the thickness of the coating film, as well as for improving the dispersibility of the photoacid generating agent, and the like. These organic solvents can be organic solvents that have been conventionally blended in various high energy beam-curable compositions, without any particular restrictions.

Suitable examples of the organic solvent include: (poly)alkylene glycol monoalkyl ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, propylene glycol monoethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, and the like; (poly)alkylene glycol monoalkyl ether acetates such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate (PGMEA), propylene glycol monoethyl ether acetate, and the like; other ethers such as diethylene glycol dimethyl ether, diethylene glycol methyl ethyl ether, and diethylene glycol diethyl ether; ketones such as methyl ethyl ketone, methyl isobutyl ketone, cyclohexanone, 2-heptanone, 3-heptanone, 4-heptanone, 5-methyl-3-heptanone, 2,4-dimethyl-3-pentanone, 2,6-dimethyl-4-heptanone, and the like; alkyl lactates such as methyl 2-hydroxypropionate, ethyl 2-hydroxypropionate, and the like; other esters such as ethyl 2-hydroxy-2-methylpropionate, methyl-3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanate, 3-methoxybutylacetate, 3-methyl-3-methoxybutylacetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, ethyl 2-oxobutanoate, and the like; aromatic hydrocarbons such as toluene, xylene, mesitylene, cumene, propylbenzene, diethylbenzene, 1,3-diisopropylbenzene, and the like; aromatic ethers such as anisole, phenethol, 2-methoxytoluene, 3-methoxytoluene, 4-methoxytoluene, 3,4-dimethoxytoluene, 1,4-bis(methoxymethyl)benzene, and the like. The organic solvent may be used alone or in combination with a plurality of organic solvents, taking into consideration the miscibility with component (A) to component (C).

The amount of organic solvent is not particularly limited, and is set appropriately based on the miscibility with (A) phenolic hydroxyl group-containing branched organopolysiloxane, the film thickness of the coating film formed by the high energy beam-curable composition, and the like. Typically, an amount of 50 to 10000 parts by mass per 100 parts by mass of component (A) is used. In other words, a solvent concentration of 1 to 50 mass % of branched curable organopolysiloxane is preferable, and a range of 2 to 40 mass % is more preferable.

The cured product obtained from the high energy beam-curable composition of the present invention can be designed so that the desired physical properties of the cured product and the curing speed of the curable composition can be obtained according to the molecular structure of component (A) and the number of phenolic hydroxyl groups, alcoholic hydroxyl groups, and carboxyl groups per molecule, and according to the molecular structure and amount of component (B) and component (C) added, and the viscosity of the curable composition can be designed to achieve the desired value according to the amount of component (D). Furthermore, the cured product obtained by curing the high energy beam-curable composition of the present invention is also included in the scope of the present invention. The shape of the cured product obtained from the curable composition of the present invention is not particularly limited, and it may be a thin film coating layer, may be a sheet-like molded product or the like, or may be used as a sealing material for a laminated body, display device, or the like or as an intermediate layer. The cured product obtained from the composition of the present invention is preferably in the form of a thin film coating layer, and is particularly preferably a thin film insulating coating layer.

The high energy beam-curable composition of the present invention is suitably used as a coating agent, particularly as an insulating coating agent for an electronic device or electrical device. The composition is also suitable for use as a resist material when using short wavelength light such as EUV of an excimer laser as a light source.

### [Other Additives]

In addition to the aforementioned components, additional additives may be added to the composition of the present invention if desired. Examples of additives include, but are not limited to, those described below.

### [Adhesion-Imparting Agent]

An adhesion-imparting agent can be added to the high energy beam-curable composition of the present invention to improve adhesion and bonding properties to a substrate in contact with the composition. When the curable composition of the present invention is used for applications such as coating agents, sealing materials, and the like that require adhesion or close-fitting properties to a base material, an adhesion-imparting agent is preferably added to the curable composition of the present invention. An arbitrary known adhesion-imparting agent can be used, so long as the adhesion-imparting agent does not interfere with a curing reaction of the composition of the present invention.

Examples of the adhesion-imparting agent that can be used in the present invention include: organosilanes having a trialkoxysiloxy group (such as a trimethoxysiloxy group or a triethoxysiloxy group) or a trialkoxysilylalkyl group (such as a trimethoxysilylethyl group or triethoxysilylethyl groups) and a hydrosilyl group or an alkenyl group (such as a vinyl group or an allyl group), or organosiloxane oligomers having a linear structure, branched structure, or cyclic structure with approximately 4 to 20 silicon atoms; organosilanes having a trialkoxysiloxy group or a trialkoxysilylalkyl group and a methacryloxyalkyl group (such as a 3-methacryloxypropyl group), or organosiloxane oligomers having a linear structure, branched structure, or cyclic structure with approximately 4 to 20 silicon atoms; organosilanes having a trialkoxysiloxy group or a trialkoxysilylalkyl group and an epoxy group-bonded alkyl group (such as a 3-glycidoxypropyl group, a 4-glycidoxybutyl group, a 2-(3,4-epoxycyclohexyl)ethyl group, or a 3-(3,4-epoxycyclohexyl) propyl group), or organosiloxane oligomers having a linear structure, branched structure, or cyclic structure with approximately 4 to 20 silicon atoms; organic compounds having two or more trialkoxysilyl groups (such as trimethylsilyl groups or triethoxysilyl groups); reaction products of aminoalkyltrialkoxysilane and epoxy group-bonded alkyltrialkoxysilane, and epoxy group-containing ethyl polysilicate. Specific examples thereof include vinyl trimethoxysilane, allyl trimethoxysilane, allyl triethoxysilane, hydrogen triethoxysilane, 3-glycidoxypropyl trimethoxysilane, 3-glycidoxypropyl triethoxysilane, 2-(3,4-epoxycyclohexyl)ethyl trimethoxysilane, 3-methacryloxypropyl trimethoxysilane, 3-methacryloxypropyl triethoxysilane, 1,6-bis(trimethoxysilyl) hexane, 1,6-bis(triethoxysilyl) hexane, 1,3-bis[2-(trimethoxysilyl)ethyl]-1,1,3,3-tetramethyldisiloxane, reaction products of 3-glycidoxypropyl triethoxysilane and 3-aminopropyl triethoxysilane, condensation reaction products of a methylvinyl siloxane oligomer blocked with a silanol group and a 3-glycidoxypropyl trimethoxysilane, condensation reaction products of a methylvinyl siloxane oligomer blocked with a silanol group and a 3-methacryloxypropyl triethoxysilane, and tris(3-trimethoxysilylpropyl) isocyanurate.

The amount of the adhesion-imparting agent to be added to the high energy beam-curable composition of the present invention is not particularly limited. However, since it does not promote curing properties of the curable composition or discoloration of a cured product, the amount is preferably within a range of 0.01 to 5 parts by mass, or within a range of 0.01 to 2 parts by mass, relative to a total of 100 parts by mass of component (A).

### [Additional Optional Additives]

Another additive may be added to the high energy beam-curable composition of the present invention in addition to or in place of the adhesion-imparting agent described above, if desired. Examples of additives that can be used include leveling agents, silane coupling agents not included in those listed above as adhesion-imparting agents, high energy beam absorbers, antioxidants, polymerization inhibitors, fillers (reinforcing fillers, insulating fillers, thermal conductive fillers, and other functional fillers), and the like. If necessary, an appropriate additive can be added to the composition of the present invention. Furthermore, a thixotropy imparting agent may also be added to the composition of the present invention, if necessary, particularly when used as a sealing agent.

### [Method of Manufacturing Cured Film]

The method of producing the cured film is not limited in particular, as long as the method is capable of curing the film made of the high energy beam-curable composition described above. Known lithographic processes can be preferably applied to produce a patterned cured film. A typical recommended manufacturing method preferably includes the following.
1) forming a coating film of the aforementioned high energy beam-curable composition on a base material;
2) heating the resulting coating film for a short period of time at a temperature of about 100° C. or less to remove the solvent;
3) performing position-selective exposure of the coating film;
4) developing the exposed coating film; and
5) heating the patterned cured film to a temperature exceeding 100° C. to fully cure the film.

If necessary, a short heating step can be inserted between steps 3) and 4).

This manufacturing method is described below in detail.

Various substrates can be used as the substrate, including glass substrates, silicon substrates, glass substrates coated with transparent conductive films, and the like.

Known methods for applying the high energy beam-curable composition on a substrate use coating equipment such as spin coaters, roll coaters, bar coaters, slit coaters, and the like.

The applied curable composition is usually heated and dried to remove the solvent (pre-bake step). Typical methods include drying on a hot plate at 80 to 120° C., preferably 90 to 100° C. for 1 to 2 minutes, and leaving at room temperature for several hours, or heating in a hot air heater or infrared heater for tens of minutes to several hours.

Position-selective exposure of the coating film is usually performed through a photomask or the like, using a known active energy beam light source, such as high energy beam sources like high-pressure mercury vapor lamps, metal halide lamps, and LED lamps, laser light sources such as excimer laser lights, and UEV. Negative or positive type photomasks can be used, depending on the properties of the curable composition. The energy dose to be irradiated depends on the structure of the curable composition, but typically ranges from 40 to 2000 mJ/cm². Furthermore, if necessary, the composition coating film after exposure may be subjected to a heat treatment (post-exposure bake (PEB)) to enhance the degree of curing. The conditions for this are usually a temperature of 100 to 150° C. for a period of 1 to 1.5 minutes.

Development using a developing solution is performed in order to form a pattern with the desired shape. Alkaline aqueous solutions and organic solvents are known as developer solutions, but development with an alkaline aqueous solution is the most common. Both aqueous solutions of inorganic bases and aqueous solutions of organic bases can be used as the alkaline solution. Suitable developing solutions include basic aqueous solutions such as sodium hydroxide, potassium hydroxide, sodium carbonate, ammonia, quaternary ammonium salts, and the like. Aqueous solutions of tetramethylammonium hydroxide (TMAH) are particularly preferable. The developing method is not particularly limited, and for example, a dipping method, spray method, or the like can be used.

As described above, the phenolic hydroxyl group-containing branched organopolysiloxane of the present invention and the high energy beam-curable composition containing this compound as a main component will have excellent high energy beam curability while also having particularly excellent alkali solubility, and therefore have the advantages that pattern formation can be carried out easily and with high precision, particularly when subjected to a development step using an aqueous alkali solution, and the obtained cured film has excellent mechanical strength and transparency.

The patterned cured film after development may be subjected to post-heating, if necessary. The post-heating temperature is not limited as long as no thermal decomposition or deformation occurs in the patterned cured film, but a temperature of 150 to 250° C. is preferable, and 150 to 200° C. is more preferable.

The aforementioned operations can form a cured film of high energy beam-curable composition patterned with a desired shape.

### [Application]

Specifically, the high energy beam-curable composition of the present invention is particularly useful as a material for forming an insulating layer for various articles, particularly electronic and electrical devices and as a photoresist material. Furthermore, the curable composition of the present invention provides favorable transparency of the cured product obtained therefrom, and is also suitable as a material for forming an insulating layer for touch panels, displays and other display devices. In this case, an arbitrary desired pattern may be formed as described above on the insulating layer if necessary. Therefore, a display device such as a touch panel, display, or the like containing an insulating layer obtained by curing the high energy beam-curable composition of the present invention is also an aspect of the present invention.

Furthermore, the curable composition of the present invention can also be used to form an insulating coating layer (insulating film) by curing after coating an article. Therefore, the composition of the present invention can be used as an insulating coating agent. Furthermore, a cured product formed by curing the curable composition of the present invention can be used as an insulative coating layer.

An insulating film formed from the curable composition of the present invention can be used for various applications other than the aforementioned display device. In particular, use is possible as a component of an electronic device or as a member used in a process of manufacturing the electronic device. Electronic devices include semiconductor devices, magnetic recording heads, and other electronic apparatuses. For example, the curable composition of the present invention can be used in an insulating film of a semiconductor device, such as an LSI, system LSI, DRAM, SDRAM, RDRAM, D-RDRAM, or a multi-chip module multilayer circuit board, an interlayer insulating film for a semiconductor, an etch stopper film, a surface protection film, a buffer coat film, a passivation film in LSI, a cover coat for a flexible copper cladding plate, a solder resistant film, and a surface protection film for an optical device.

The present invention is further described below on the basis of Examples, but the present invention is not limited to the Examples below.

### EXAMPLES

Synthesis of the phenolic hydroxyl group-containing branched organopolysiloxane, preparation and evaluation of a high energy beam-curable composition, and preparation and evaluation of a cured product thereof of the present invention will now be described in detail with reference to examples.

### [Appearance of Curable Composition and Cured Product]

The curable composition and cured product were visually observed to determine the appearance.

### [Alkaline Solubility of Curable Branched Organopolysiloxane]

A 20 mass % PGMEA solution of each curable branched organopolysiloxane was spin-coated onto an optical glass substrate to a thickness of 0.3 to 0.5 μm, and heated (pre-baked) at 90° C. for 1.5 minutes using a hot plate to form a coating film. The film was then developed in a 2.38% aqueous solution of tetramethylammonium hydroxide (TMAH) at 25° C. for 1 minute, followed by an immersion water wash in a water bath at room temperature (25° C.). The water wash time was 15 seconds. After rinsing and drying to remove water, the glass substrate was visually observed to determine the solubility (developability) in alkaline solutions using the following criteria.
A: Completely dissolved: Paint film is completely removed
B: Almost dissolved: A tiny amount of paint residue (scum) is observed
C: Partially dissolved: Large amount of scum (more than 20% of coating area) observed
D: Insoluble

### [High Energy Beam Curability of Curable Composition]

A PGMEA solution of each curable composition (curable branched organopolysiloxane concentration: 20 mass %) was used to form a coating of the curable composition by the same method as above. This coating film was irradiated with a high energy beam from a high pressure mercury lamp (accumulated light amount at 254 nm: 2000 mJ/cm²) to obtain a cured coating film. The high-energy beam curability was determined using the following criteria.
A: Cured coating is insoluble in the TMAH dissolution test
B: Only the edge portions of the cured coating (less than 5% of the total area of the cured coating) are dissolved in the TMAH dissolution test
C: Cured coating is completely or almost completely dissolved in the TMAH dissolution test.

### [Synthesis Example 1] Synthesis of Phenolic Hydroxyl Group-Containing Branched Organopolysiloxane (A-1)

A 200 mL three-neck flask equipped with a thermometer and a nitrogen inlet tube was charged with 40.1 g of dimethylsiloxy-capped phenylsilsesquioxane (silicon-bonded hydrogen content: 0.66 mass %), 10 g of toluene, 46.2 g of t-butoxystyrene, and a platinum (0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 100° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched phenylsilsesquioxane in which silicon-bonded hydrogen atoms were replaced with t-butoxyphenylethyl groups.

A 200 mL three-neck flask equipped with a thermometer and a nitrogen inlet tube was charged with 84.46 g of a branched phenylsilsesquioxane substituted with t-butoxyphenylethyl groups and 157 g of a 90 mass % aqueous formic acid solution, and then heated at 100° C. for 5 hours, after which completion of the reaction was confirmed. Volatile components were removed, and the residue was diluted with 100 ml of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

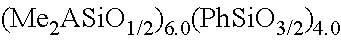

Here, Me represents a methyl group, Ph represents a phenyl group, and A represents a (CH₂)₂C₆H₄OH group.

Gel permeation chromatogram analysis showed that the weight average molecular weight (Mw) and polydispersity (PDI) of (A-1) were 1700 and 1.36, respectively.

### [Synthesis Example 2] Synthesis of Phenolic Hydroxyl Group-Containing Branched Organopolysiloxane (A-2)

A 200 mL three-neck flask equipped with a thermometer and a nitrogen inlet tube was charged with 32.0 g of dimethylsiloxy-capped silica (silicon-bonded hydrogen content: 0.97 mass %), 54.3 g of t-butoxystyrene, and a platinum(0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 120° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched silica in which silicon-bonded hydrogen atoms were replaced with t-butoxyphenylethyl groups.

A 200 mL three-neck flask equipped with a thermometer and a nitrogen inlet tube was charged with 82.8 g of a branched silica substituted with t-butoxyphenylethyl groups and 157 g of a 90 mass % aqueous formic acid solution, and then heated at 100° C. for 4 hours, after which completion of the reaction was confirmed. Volatile components were removed, and the residue was diluted with 100 mL of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

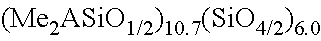

Here, Me represents a methyl group, and A represents a (CH₂)₂C₆H₄OH group.

Gel permeation chromatogram analysis showed that the weight average molecular weight (Mw) and polydispersity (PDI) of (A-2) were 2400 and 1.14, respectively.

### [Synthesis Example 3] Synthesis of Phenolic Hydroxyl Group-Containing Curable Branched Organopolysiloxane (A-3)

A 200 mL three-neck flask equipped with a thermometer and a nitrogen inlet tube was charged with 13.2 g of dimethylsiloxy-capped silica (silicon-bonded hydrogen content: 0.97 mass %), 36.7 g of O,O-bistrimethoxysilyl-4-vinylcatechol, and a platinum (0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 120° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched silica in which silicon-bonded hydrogen atoms were replaced with 3,4-bistrimethylsiloxyphenylethyl groups.

A 200 mL three-neck flask equipped with a thermometer and a nitrogen inlet tube was charged with 48.0 g of branched silica substituted with 3,4-bistrimethylsiloxyphenylethyl groups, 100 mL of tetrahydrofuran, 5 g of a 90 mass % aqueous formic acid solution, and 10.0 g of purified water, and the mixture was heated at 60° C. for 90 minutes, after which the completion of the reaction was confirmed. The volatile components were removed and the mixture was diluted with 100 mL of PGMEA to obtain a PGMEA solution of the product. Analysis by ¹³C and ²⁹Si NMR spectroscopy confirmed the product to be a branched organopolysiloxane having the following average composition:

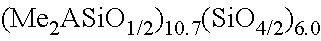

Here, Me represents a methyl group, and A represents a (CH₂)₂C₆H₃(OH)₂ group.

Gel permeation chromatogram analysis showed that the weight average molecular weight (Mw) and polydispersity (PDI) of (A-3) were 2400 and 1.04, respectively.

### [Synthesis Example 4] Synthesis of Branched Organopolysiloxane Having a Phenolic Hydroxyl Group and a Carboxyl Group (A-4)

A 200 mL three-neck flask equipped with a thermometer and a nitrogen inlet tube was charged with 40.1 g of dimethylsiloxy-capped phenylsilsesquioxane (silicon-bonded hydrogen content: 0.66 mass %), 10 g of toluene, 46.2 g of t-butoxystyrene, and a platinum(0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 100° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched phenylsilsesquioxane in which silicon-bonded hydrogen atoms were replaced with t-butoxyphenylethyl groups.

A 200 mL three-neck flask equipped with a thermometer and a nitrogen inlet tube was charged with 84.46 g of a branched phenylsilsesquioxane substituted with t-butoxyphenylethyl groups and 157 g of a 90 mass % aqueous formic acid solution, and then heated at 100° C. for 20 hours, after which completion of the reaction was confirmed. Volatile components were removed, and the residue was diluted with 100 ml of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

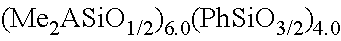

Here, Me represents a methyl group, Ph represents a phenyl group, and A represents a (CH₂)₂C₆H₄OH group.

Gel permeation chromatogram analysis showed that the weight average molecular weight (Mw) and polydispersity (PDI) of the aforementioned products were 1700 and 1.36, respectively.

A 200 mL three-neck flask equipped with a thermometer and a nitrogen inlet tube was charged with 58.6 g of the aforementioned product, 90 g of PGMEA, 7.2 g of succinic anhydride, and 0.12 g of tetramethylguanidine, and then heated at 90° C. for 4 hours, after which completion of the reaction was confirmed. After cooling to room temperature, 3 g of Kyoward 700PL was added to neutralize the reaction system. A white solid was filtered out to give a PGMEA solution of the product. Analysis by ¹³C and ²⁹Si NMR spectroscopy confirmed the product to be a branched organopolysiloxane having the following average composition:

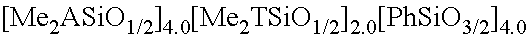

Here, Me represents a methyl group, Ph represents a phenyl group, A represents a (CH₂)₂C₆H₄OH group, and T represents a (CH₂)₂C₆H₄O(C═O)(CH₂)₂CO₂H group.

Gel permeation chromatogram analysis showed that the weight average molecular weight (Mw) and polydispersity (PDI) of (A-4) were 1900 and 1.36, respectively.

### [Synthesis Example 5] Synthesis of Branched Organopolysiloxane Having a Phenolic Hydroxyl Group and a Carboxyl Group (A-5)

A 200 mL three-neck flask equipped with a thermometer and a nitrogen inlet tube was charged with 32.0 g of dimethylsiloxy-capped silica (silicon-bonded hydrogen content: 0.97 mass %), 54.3 g of t-butoxystyrene, and a platinum (0)-1,3-divinyl-1,1,3,3-tetramethyldisiloxane complex solution (platinum amount: 4.5 mass %; in an amount such that the platinum metal was 2 ppm relative to the substrate), and then the mixture was heated at 70° C. for 30 minutes and at 120° C. for 2 hours. After confirming completion of the reaction by infrared spectroscopic analysis, the volatile components were removed to obtain a pale yellow oily product. Analysis by ¹³C and ²⁹Si NMR spectroscopy confirmed that the product was a branched silica in which silicon-bonded hydrogen atoms were replaced with t-butoxyphenylethyl groups.

A 200 mL three-neck flask equipped with a thermometer and a nitrogen inlet tube was charged with 82.8 g of a branched silica substituted with t-butoxyphenylethyl groups and 157 g of a 90 mass % aqueous formic acid solution, and then heated at 100° C. for 4 hours, after which completion of the reaction was confirmed. Volatile components were removed, and the residue was diluted with 100 mL of PGMEA and then washed with aqueous sodium bicarbonate solution and purified water to obtain a PGMEA solution of the product. Analysis by ¹³C and ²⁹Si NMR spectroscopy confirmed the product to be a branched organopolysiloxane having the following average composition:

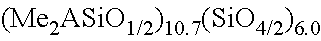

Here, Me represents a methyl group, and A represents a (CH₂)₂C₆H₄OH group.

Gel permeation chromatogram analysis showed that the weight average molecular weight (Mw) and polydispersity (PDI) of the aforementioned products were 2400 and 1.14, respectively.

A 200 mL three-neck flask equipped with a thermometer and a nitrogen inlet tube was charged with 41.6 g of the aforementioned product, 178 g of PGMEA, 1.7 g of succinic anhydride, and 0.03 g of tetramethylguanidine, and then heated at 90° C. for 4 hours, after which completion of the reaction was confirmed. After cooling to room temperature, 1.5 g of Kyoward 700PL was added to neutralize the reaction system. A white solid was filtered out to give a PGMEA solution of the product. Analysis by ¹³C and ²⁹Si NMR spectroscopy confirmed the product to be a branched organopolysiloxane having the following average composition:

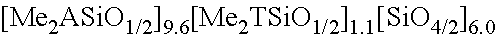

Here, Me represents a methyl group, A represents a (CH₂)₂C₆H₄OH group, and T represents a (CH₂)₂C₆H₄₀ (C═O)(CH₂)₂CO₂H group.

Gel permeation chromatogram analysis showed that the weight average molecular weight (Mw) and polydispersity (PDI) of (A-5) were 2400 and 1.36, respectively.

### [Examples 1-1 to 1-5, Comparative Examples 1-1 to 1-4] Alkali Solubility of Curable Branched Organopolysiloxane

The alkali solubility was evaluated using a 20 mass % PGMEA solution of the branched organopolysiloxane shown below, and the results are compiled in Table 1.
A-1: Phenolic hydroxyl group-containing branched organopolysiloxane obtained in Synthesis Example 1
A-2: Phenolic hydroxyl group-containing branched organopolysiloxane obtained in Synthesis Example 2
A-3: Phenolic hydroxyl group-containing branched organopolysiloxane obtained in Synthesis Example 3
A-4: Branched organopolysiloxane having a phenolic hydroxyl group and a carboxyl group, obtained in Synthesis Example 4
A-5: Branched organopolysiloxane having a phenolic hydroxyl group and a carboxyl group, obtained in Synthesis Example 5
P-1: Branched organopolysiloxane which is solid at room temperature and has an average composition ([Me₂HSiO_{1/2}]_{5.0}[PhSiO_{3/2}]_{15.0}) similar to the dimethylsiloxy group-capped phenylsilsesquioxane used in Synthesis Example 1;
P-2: Branched organopolysiloxane which is liquid at room temperature and has an average composition ([Me₂HSiO_{1/2}]_{6.0}[PhSiO_{3/2}]_{4.0}) similar to the dimethylsiloxy group-capped phenylsilsesquioxane used in Synthesis Example 1;
P-3: Branched organopolysiloxane which is solid at room temperature and has an average composition ([Me₂HSiO_{1/2}]_{29.0}[SiO_{4/2}]_{36.0}) similar to the dimethylsiloxy group-capped silica used in Synthesis Example 2;
P-4: Branched organopolysiloxane which is liquid at room temperature and has an average composition ([Me₂HSiO_{1/2}]_{10.7}[SiO_{4/2}]_{6.0}) similar to the dimethylsiloxy group-capped silica used in Synthesis Example 2.

TABLE 1

| | Experiment example | | | | | | | | |
|---|---|---|---|---|---|---|---|---|---|
| | Example | Example | Example | Example | Example | Comparative | Comparative | Comparative | Comparative |
| | 1-1 | 1-2 | 1-3 | 1-4 | 1-5 | Example 1-1 | Example 1-2 | Example 1-3 | Example 1-4 |
| Component | A-1 | A-2 | A-3 | A-4 | A-5 | P-1 | P-2 | P-3 | P-4 |
| (Branched | | | | | | | | | |
| organopoly- | | | | | | | | | |
| siloxane) | | | | | | | | | |
| In formula (1) | 1.50 | 1.78 | 1.78 | 1.50 | 1.78 | 0.33 | 1.50 | 0.82 | 1.78 |
| a/(b + c + d) | | | | | | | | | |
| Alkali solubility | C | B | A | A | A | D | *1 | *2 | *1 |
| evaluation | | | | | | | | | |

*1: Evaluation was impossible because a solid coating film was not formed.
*2: Evaluation was impossible because a uniform coating film was not formed.

### [Examples 2 to 4, and Comparative Example 2] Evaluation of Curable Branched Organopolysiloxane Composition

The following PGMEA solutions of a branched organopolysiloxane, crosslinking agent, and curing catalyst were mixed in the compositions shown in Table 2 (parts by mass; branched organopolysiloxane is calculated on the basis of solid content), and the mixtures were filtered through a membrane filter having a pore size of 0.2 μm to prepare high energy beam-curable compositions.

### Curable Branched Organopolysiloxanes:

A-3: Phenolic hydroxyl group-containing branched organopolysiloxane obtained in Synthesis Example 3
A-5: Branched organopolysiloxane having a phenolic hydroxyl group and a carboxyl group, obtained in Synthesis Example 5
P-1: Branched organopolysiloxane which is solid at room temperature and has the configuration of ([Me₂HSiO_{1/2}]_{5.0}[PhSiO_{3/2}]_{15.0})

### Photoacid Generating Agent:

B-1: Tri-p-tolylsulfonium trifluoromethanesulfonate (product name: TS-01; manufactured by Sanwa Chemical Co., Ltd.)

### Curing Agent:

C-1: Tetrakis methoxymethyl glycoluril (product name: Nikalac MX-270; manufactured by Sanwa Chemical Co., Ltd.)

TABLE 2

| | | | | Comparative |
|---|---|---|---|---|
| Component | Example 2 | Example 3 | Example 4 | Example 2 |
| (A-3; as | 100 | | | |
| solid content) | | | | |
| (A-5; as | | 100 | 100 | |
| solid content) | | | | |
| (P-1) | | | | 100 |
| (B-1) | 2 | 2 | 2 | 2 |
| (C-1) | 30 | 10 | | 30 |
| Total | 132 | 112 | 102 | 132 |
| Appearance of curable | Clear | Clear | Clear | Clear |
| composition | | | | |
| High energy beam | A | A | A | C |
| curability | | | | |
| Appearance of cured | Clear | Clear | Clear | Uncured |
| product | | | | |
| Alkaline solubility | A | A | A | D |

### SUMMARY

As shown in Table 1, the coating films formed from the phenolic hydroxyl group-containing branched organopolysiloxanes (including co-modified types) of the present invention exhibited alkali solubility sufficient for practical use, and some (A-2 to A-5) exhibited particularly excellent alkali solubility. Note that the curable branched organopolysiloxanes according to the comparative examples all had poor alkali solubility or were insoluble in alkali, and could not be used for development with an aqueous alkaline solution.

Furthermore, as shown in Table 2, the high energy beam-curable organopolysiloxane compositions of the present invention (Examples 2 to 4) had favorable high energy beam curability. Furthermore, the cured coating film formed by irradiation with a high energy beam was transparent and exhibited sufficiently high coating toughness. On the other hand, the branched polyorganosiloxane that did not have a phenolic hydroxyl group (Comparative Example 2) had poor alkali solubility and also did not have curing properties, so use would be difficult in the photopatterning process.

### INDUSTRIAL APPLICABILITY

The phenolic hydroxyl group-containing branched organopolysiloxane of the present invention and the curable composition containing this compound as a main component, in particular, the high energy beam-curable composition, have excellent high energy beam curability while also having excellent alkali solubility, and therefore have the advantages that pattern formation can be carried out easily and with high precision, particularly when subjected to a development step using an aqueous alkali solution, and the obtained cured film has excellent mechanical strength and transparency. Therefore, the organopolysiloxanes and the like are particularly suitable as materials, especially patterning materials, coating materials, and resist materials for forming insulating layers for touch panels and display devices such as displays, especially flexible displays.

1. A phenolic hydroxyl group-containing branched organopolysiloxane expressed by the following average unit formula (1): 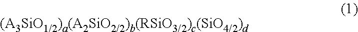
where R represents a group selected from hydrogen atoms, unsubstituted or fluorine-substituted monovalent hydrocarbon groups, alkoxy groups, and hydroxyl groups;
each A independently represents one or more group selected from the same groups as R,
groups M¹ expressed by the following formula (21): 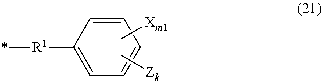
where R¹ is a divalent hydrocarbon group having 2 to 6 carbon atoms, X is a hydroxyl group, Z is a monovalent group expressed by —OR³ where R³ is an acid-dissociable group, m1 is a number in a range of 1 to 3, k is a number in a range of 0 to 3, and * is a silicon atom-bonding site on the organopolysiloxane,
groups M² is expressed by the following formula (22): 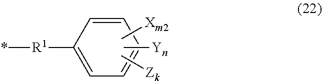
where R¹, X, and Z are the same groups as described above,
Y is a monovalent hydrophilic group expressed by —Wₚ—R²_{q}—CO₂H where W represents a divalent linking group selected from O(C═O), NR⁵(C═O), and S(C═O) groups, p is 0 or 1, q is 0 or 1, R² is a linear, branched or cyclic divalent hydrocarbon group having 2 to 12 carbon atoms which may optionally contain an oxygen atom or a sulfur atom, and R⁵ represents a hydrogen atom or a methyl group,
m2 is 0 or 1, n is a number in a range of 1 to 3, k is a number in a range of 0 to 3, and * is a silicon atom-bonding site on the organopolysiloxane,
groups J expressed by the following formula (3): 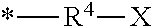
where R⁴ represents a divalent hydrocarbon group with 2 to 6 carbon atoms, and X represents the aforementioned groups; and
groups L expressed by the following formula (4): 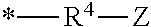
where R⁴ and Z represents the same groups as described above; and
at least one of all A represents M¹, and a, b, c, and d are numbers satisfying the following conditions: 0≤a, 0≤b, 0<(a+b), and 0<(c+d).

2. The phenolic hydroxyl group-containing branched organopolysiloxane according to claim 1, wherein the number of silicon atoms in each molecule is 50 or less.

3. The phenolic hydroxyl group-containing branched organopolysiloxane according to claim 1, wherein the number of silicon atoms in each molecule is in a range of 5 to 20.

4. The phenolic hydroxyl group-containing branched organopolysiloxane according to claim 1, where in the average unit formula (1), a is a number of 1 or more.

5. The phenolic hydroxyl group-containing branched organopolysiloxane according to claim 1, where in the average unit formula (1), b is 0.

6. The phenolic hydroxyl group-containing branched organopolysiloxane according to claim 1, where in the average unit formula (1), a, b, c, and d are numbers that satisfy the following condition: 0.5≤a/(b+c+d)≤2.0.

7. The phenolic hydroxyl group-containing branched organopolysiloxane according to claim 1, expressed by the following average unit formula (1-1) or (1-2): 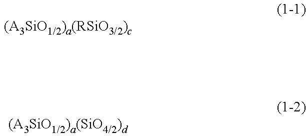
where R and A are the same groups as defined above, and a, c, and d are numbers satisfying the above conditions.

8. The phenolic hydroxyl group-containing branched organopolysiloxane according to claim 1, having a weight average molecular weight of 1,000 or more and 3,000 or less calculated as standard polystyrene measured by gel permeation chromatography, and a polydispersity index (PDI) related to the molecular weight distribution of 1.5 or less.

9. The phenolic hydroxyl group-containing branched organopolysiloxane according to claim 1, where in formula (21), ml is 1 or 2.

10. The phenolic hydroxyl group-containing branched organopolysiloxane according to claim 1, where in formula (21) and formula (22), k is 0, and group L is not included in each molecule.

11. The phenolic hydroxyl group-containing branched organopolysiloxane according to claim 1, which does not contain a group M² and a group J in each molecule.

12. The phenolic hydroxyl group-containing branched organopolysiloxane according to claim 1, wherein a coating film made of the organopolysiloxane is soluble in an aqueous alkaline solution so as to have a mass reduction rate of 90 mass % or more when the phenolic hydroxyl group-containing branched organopolysiloxane is applied to a glass plate so that the thickness after application is 0.5 μm, after which the coating film is immersed in a 2.38 mass % aqueous solution of tetramethylammonium hydroxide (TMAH) for 1 minute and then washed with water.

13. A curable composition, comprising: the phenolic hydroxyl group-containing branched organopolysiloxane according to claim 1.

14. A high energy beam-curable composition, comprising:
(A) the phenolic hydroxyl group-containing branched organopolysiloxane according to claim 1;
(B) a photoacid generating agent in an amount of 0.1 to 20 parts by mass per 100 parts by mass of component (A);
(C) a crosslinking agent in an amount of 0 to 30 parts by mass per 100 parts by mass of component (A); and
(D) an organic solvent.

15. An insulating coating agent, comprising: the high energy beam-curable composition according to claim 14.

16. A resist material, comprising: the high energy beam-curable composition according to claim 14.

17. A cured product of the high energy beam-curable composition according to claim 14.

18. A method of using the cured product according to claim 17 as an insulating coating layer.

19. A display device, comprising: a layer containing the cured product according to claim 17.
